(19) United States
(12) Patent Application Publication
(10) Pub. No.: US 2024/0421796 A1
(43) Pub. Date: Dec. 19, 2024

(54) CRYSTAL RESONATOR DEVICE WITH THERMISTOR

(71) Applicant: DAISHINKU CORPORATION, Kakogawa-shi, Hyogo (JP)

(72) Inventor: Yoshinari MORIMOTO, Kakogawa-shi (JP)

(73) Assignee: DAISHINKU CORPORATION, Kakogawa-shi, Hyogo (JP)

(21) Appl. No.: 18/706,389

(22) PCT Filed: Nov. 7, 2022
(86) PCT No.: PCT/JP2022/041438

§ 371 Date: May 1, 2024

(30) Foreign Application Priority Data
Nov. 9, 2021 (JP) 2021-182803

(51) Int. Cl. H03H 9/19; H03H 9/10

(52) U.S. Cl. CPC H03H 9/19; H03H 9/1021; H03H 9/1035; H03H 9/1042

(57) ABSTRACT

A crystal resonator device with a thermistor according to one or more embodiments may include: a package including an upper housing and a lower housing; a crystal resonator plate housed in the upper housing; a thermistor housed in the lower housing; and a lid hermetically sealing the upper housing. Excitation electrodes of the crystal resonator plate are each constituted of a plurality of metal film layers, and a main layer thereof is made of Au. The thermistor has a single plate-like thermistor element as a base material. Working electrodes of the thermistor are each constituted of a plurality of metal film layers, and a main layer thereof is made of Au.

### TECHNICAL FIELD

The present invention relates to a crystal resonator device with a thermistor, which is made by conductively bonding, to a package, a crystal resonator plate and a thermistor.

### BACKGROUND ART

Recently, various electronic devices have improved in accuracy, and according to this improvement, there is a demand for temperature-compensating crystal oscillator circuits that compensate frequency fluctuations associated with changes in the environmental temperature. As a crystal resonator device corresponding to the above circuit, a crystal resonator device with a thermistor is widely used, which is constituted of a crystal resonator and a thermistor as a temperature sensor mounted on the crystal resonator.

A temperature-compensated frequency signal can be obtained by measuring the environmental temperature of the crystal resonator using a thermistor, and furthermore by transmitting frequency information and temperature information to a temperature compensation circuit externally mounted. Thus, it is possible to maintain highly accurate operations of the electronic devices.

Such a crystal resonator device with a thermistor has a configuration in which: a crystal resonator plate having excitation electrodes is housed in a package made of ceramic; and a thermistor is mounted on the outer side of the package so as to detect the environmental temperature that surrounds the crystal resonator (see Patent Document 1).

The above-described thermistor, which is commercially available and actually used, has a configuration in which a plurality of thermistor material layers and working electrodes are laminated on each other, and its thickness is about 0.1 mm to 0.3 mm.

### PRIOR ART DOCUMENT

### Patent Document

[Patent Document 1] JP 5900582

### SUMMARY OF THE INVENTION

### Problem to be Solved by the Invention

The above-described thermistor is required to detect changes in the temperature surrounding the crystal resonator with reduced time lag. However, since the conventionally used thermistor has a laminated structure, it is necessary to have a certain thickness (height).

One specific example of the size of the conventional thermistor as a temperature sensor, which is mounted on a package together with the crystal resonator, is: 0.2 to 0.3 mm in length, 0.4 to 0.6 mm in width, and 0.1 to 0.3 mm in height.

When the thermistor has such a size, the height is relatively large compared to the other dimensions. Thus, heat of the mounting electrode of the package, on which the thermistor is mounted, takes time to be conducted over the entire thermistor. In addition to the laminated structure of the thermistor, the above configuration results in long time to detect the temperature.

Furthermore, the electrode film structure formed on the crystal resonator is a laminated metal film structure having a Cr layer as a base layer and a Au layer as a main layer, while the electrode film structure formed on the thermistor is a laminated metal film structure made of, for example, a Ag layer, a Ni layer and a Sn layer. Thus, both electrode film structures are different from each other in the heat conductivity. In this case also, the change in the temperature surrounding the crystal resonator is occasionally detected with time lag.

As a result, the temperature of the crystal resonator cannot be correctly detected. Thus, an appropriate temperature compensation cannot be performed in the temperature compensation circuit, and thus a correct frequency signal is prevented from being provided to the electronic device, which leads to degradation of the operational reliability of the electronic device.

The present invention was made in consideration of the above problems, an object of which is to provide a crystal resonator device with a thermistor, which is adaptable to micro-miniaturization and micro-thinning and has excellent electrical characteristics. This thermistor stably and appropriately detects the change of the temperature of the crystal resonator device.

### Means for Solving the Problem

A crystal resonator device with a thermistor of the present invention includes: a crystal resonator plate on respective surfaces of which a pair of excitation electrodes each constituted of a plurality of metal film layers is formed; a single plate-like thermistor on a surface of which a pair of working electrodes each constituted of a plurality of metal film layers is formed; and a single package in which the crystal resonator plate and the single plate-like thermistor are housed. A main layer of each of the pair of excitation electrodes and a main layer of each of the pair of working electrodes are made of the same metal material.

Also, as another configuration, a crystal resonator device with a thermistor includes a crystal resonator device and a single plate-like thermistor described below. The crystal resonator device includes: a crystal resonator plate on respective surfaces of which a pair of excitation electrodes each constituted of a plurality of metal film layers is formed; a first sealing member bonded to a first main surface of the crystal resonator plate; and a second sealing member bonded to a second main surface of the crystal resonator plate. On a surface of the single plate-like thermistor, a pair of working electrodes each constituted of a plurality of metal film layers is formed. The single plate-like thermistor is bonded to the first sealing member of the crystal resonator device. A main layer of each of the pair of excitation electrodes and a main layer of each of the pair of working electrodes are made of the same metal material.

Examples of the metal film layers include: a base layer that makes contact with the crystal resonator plate or the plate-like thermistor element; a barrier layer that prevents the molten metal film from causing mutual melting of the upper and lower layers; and a main layer that principally functions as an electrode. The main layer is often formed on the surface layer, however, another functional layer may also be formed on the surface layer for the purpose of improving bondability to the conductive resin adhesive.

In the above-described configuration, the excitation electrode is constituted of a plurality of metal films formed on the crystal resonator plate, and the working electrode is constituted of a plurality of metal films formed on the surface of the single-plate thermistor. Since the main layer of the excitation electrodes and the main layer of the working electrodes are made of the same metal material, it is possible to reduce difference in time for transmission of heat from the outside to the crystal resonator plate and to the thermistor.

The crystal resonator plate used here has a configuration in which the excitation electrodes are formed on the respective surfaces thereof. Also, the single-plate thermistor has a configuration in which the working electrodes are formed on the surface thereof. With such a configuration in which both the crystal resonator plate and the thermistor have the single plate structure, even when the heat from the outside is conducted through the package, for example, the temperature increase information or the temperature decrease information is transmitted to the crystal resonator plate and to the thermistor with reduced time lag. Thus, the difference between the temperature detected by the thermistor as the temperature sensor and the temperature of the crystal resonator plate is extremely small, which results in accurate and appropriate temperature compensation based on the frequency information of the crystal resonator plate and the temperature information of the thermistor.

The above-described thermistor has a configuration in which electrodes are formed on the surface of the single plate-like thermistor element. A pair of working electrodes may be formed on a first main surface of the single plate-like thermistor element so that they have a certain interval therebetween. By applying electricity to the working electrodes, the function as a thermistor (to detect a changed amount of current based on the temperature) is obtained.

Also, a relay electrode may be provided on a second main surface of the plate-like thermistor element. The relay electrode and the working electrodes may face each other respectively on the front surface and the rear surface of the main surfaces. In this way, a terminal as a resistor is formed between the pair of the working electrodes formed on the plate-like thermistor element. The conductive path leads from one working electrode to the other working electrode via the relay electrode. With this configuration, it is possible to considerably increase the cross sectional area of the conductive path, and also to provide the conductive path in which the working electrodes face the relay electrode. Thus, it is possible to reduce the resistance value with a small area, which leads to characteristics easily stabilized and an improved withstand voltage.

Also, by making the respective metal materials of the above main layers have the same thickness, it is possible to reduce difference in the thermal conduction, which results in reduction of difference in time for transmission of heat to the crystal resonator plate and to the thermistor.

Also, the metal material of the main layer may be Au. The Au is a chemically stable metal material that also has an excellent thermal conductivity, which means that a chemical change of the surface such as oxidation is not likely to occur and accordingly electrical characteristics can be stabilized. By using the Au as the metal material of the main layer, the thermal conductive property can be stabilized, and thus it is possible to reduce difference in time for transmission of heat from the outside to the crystal resonator plate and to the thermistor.

Also, a metal film, which makes contact with the crystal resonator plate, of the excitation electrode may be made of Ti or Cr. A base layer, which makes contact with the thermistor, of the working electrode may be made of Ti or Cr. The Ti and the Cr have excellent adhesion to the crystal plate and the ceramic as the thermistor material when forming the film, which leads to enhancement of the mechanical strength of the excitation electrodes and the working electrodes. Furthermore, use of the same metal material as the base metal of the above respective electrodes contributes to reduction of difference in the thermal conduction, which results in reduction of difference in time for transmission of heat from the outside to the crystal resonator plate and to the thermistor.

When the electrode film formation on the crystal resonator plate and the thermistor is performed by a PVD film formation method such as a sputtering method and a vacuum deposition method, a thin film structure can be realized, which leads to improvement of the thermal conductivity by the electrode film.

The use of the Au film as the main layer as described above may be applied to the mounting electrodes formed on the package on which the thermistor is mounted. That is, the mounting electrodes each constituted of a plurality of metal film layers may be formed on the package or the first sealing member, and the main layer of each of the mounting electrodes may be made of the Au layer.

With the above-described configuration, by using the Au as the metal material of the main layer of the mounting electrodes, the thermal conductive property can be stabilized, and thus it is possible to further reduce difference in time for transmission of heat from the outside to the crystal resonator plate and to the thermistor.

The mounting electrodes may be electrically and mechanically bonded to the excitation electrodes, respectively, each via a conductive resin adhesive. The mounting electrodes may be electrically and mechanically bonded to the working electrodes, respectively, each via a conductive resin adhesive. Furthermore, the above conductive resin adhesives used here may be the same resin material.

By using the same conductive resin adhesive, it is possible to reduce difference in the thermal conduction, which results in improvement of the accuracy in the temperature detection.

Also, the above-described single plate-like thermistor may have a thickness of 0.05 mm or less.

By setting the thickness of the thermistor to 0.05 mm or less, the heat transmitted to the working electrodes (i.e. temperature fluctuation information) is quickly transmitted to the plate-like thermistor element. Thus, it is possible to improve the temperature detection performance as the thermistor.

The package can have various configurations. For example, the package may have a single housing to which the crystal resonator plate and the thermistor are conductively bonded.

By the configuration in which the crystal resonator plate and the thermistor are both housed in the single housing, it is possible to install the crystal resonator plate and the thermistor so as to be adjacent to each other, which leads to reduction of difference in the thermal change therebetween.

Furthermore, since the conductive resin adhesive is used inside the single housing, gas is not likely to be generated after bonding, which results in stability of the characteristics of the crystal resonator plate. Conventionally, the conductive bonding of the laminated thermistor is performed by solder, and thus the atmosphere inside the package is sometimes contaminated by remaining flux or the like. However, using the conductive resin adhesive to the bonding of the crystal resonator plate and to the bonding of the thermistor stabilizes the atmosphere inside the package (the vacuum atmosphere or the inert gas atmosphere), which contributes to stabilization of the characteristics of the crystal resonator plate (i.e. stabilization of the operations of the crystal resonator).

As to the housing structure of the package, the package may have two housings that are opened respectively upward and downward with the substrate being interposed therebetween. The crystal resonator plate may be conductively bonded to one housing, and the thermistor may be conductively bonded to the other housing. The crystal resonator plate and the thermistor may be located respectively on the front surface and the rear surface of the substrate so as to be opposite to each other.

With the configuration in which the crystal resonator plate and the thermistor are located respectively on the front surface and the rear surface of the substrate so as to be opposite to each other, it is possible to eliminate difference in the thermal conduction between the crystal resonator plate and the thermistor, which leads to improvement of the accuracy in the detection of the temperature.

The above-described crystal resonator plate may be an AT-cut crystal resonator plate, an SC-cut crystal resonator plate, an X-Y-cut crystal resonator plate, or the like.

### Effects of the Invention

The present invention provides a crystal resonator device with a thermistor, which is adaptable to micro-miniaturization and micro-thinning, and has excellent electrical characteristics. The thermistor appropriately detects the change of the temperature of the crystal resonator device.

### BRIEF DESCRIPTION OF THE DRAWINGS

FIG. 1 is an exploded perspective view illustrating respective components of a crystal resonator device with a thermistor according to a first embodiment.

FIG. 2 is a bottom view when the respective components of FIG. 1 are assembled.

FIG. 3 is a cross-sectional view taken from line A-A when the respective components of FIG. 1 are assembled.

FIG. 4 is a cross-sectional view illustrating an electrode film structure formed on a crystal resonator plate.

FIG. 5 is a cross-sectional view illustrating an electrode film structure formed on a thermistor.

FIG. 6 is a cross-sectional view according to a second embodiment.

FIG. 7 is a cross-sectional view according to a third embodiment.

FIG. 8 is a cross-sectional view according to a fourth embodiment.

FIG. 9 is a cross-sectional view according to a fifth embodiment.

### MODE FOR CARRYING OUT THE INVENTION

Hereinafter, the embodiments of the present invention will be described in detail with reference to the drawings.

### First Embodiment

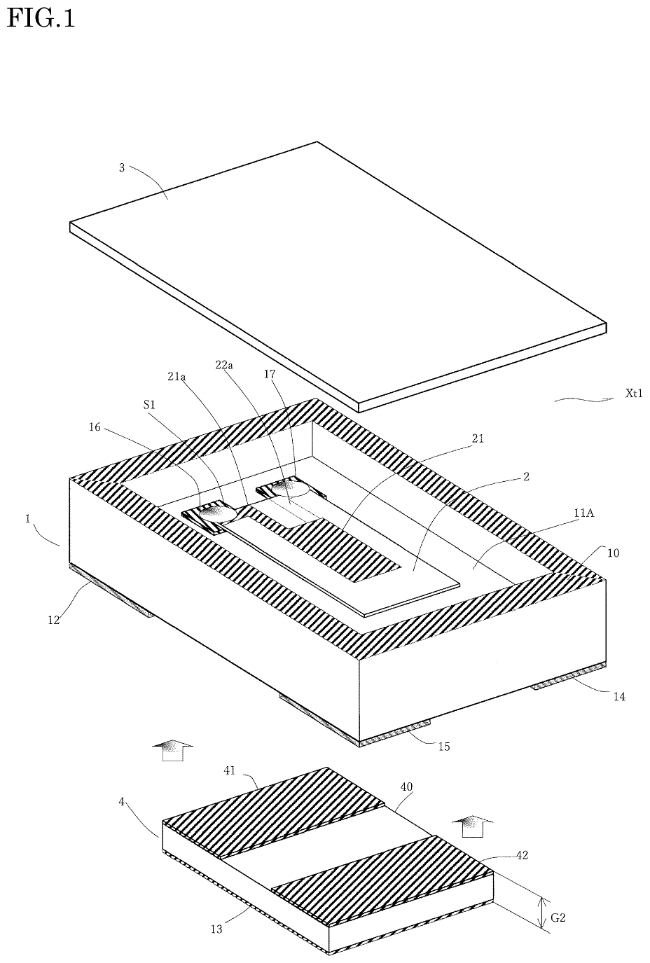

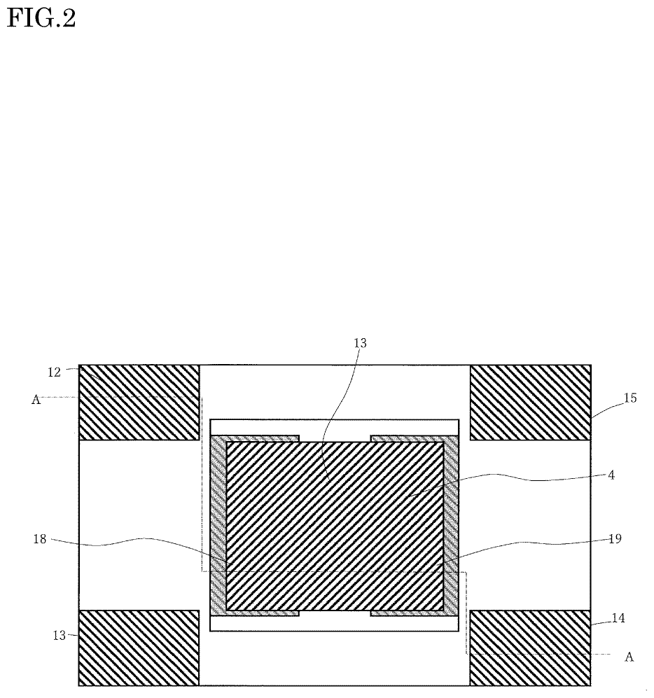

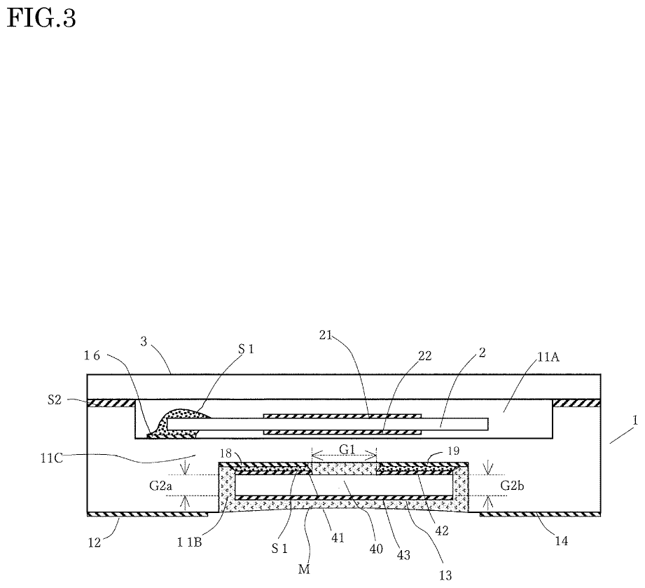

A crystal resonator device Xtl with a thermistor according to a first embodiment includes a crystal resonator device in which a crystal resonator plate 2 and a thermistor 4 are housed in a single package 1, as shown in FIGS. 1 to 3. More specifically, the crystal resonator device includes: the package 1 having an upper housing 11A and a lower housing 11B; the crystal resonator plate 2 housed in the upper housing 11A; the thermistor 4 housed in the lower housing 11B; and a lid 3 hermetically sealing the upper housing 11A. FIG. 3 is a cross-sectional view taken from line A-A of FIG. 2.

### <Configuration of Package>

As shown in FIG. 3, the package 1 made of ceramic has a substantially rectangular parallelepiped shape. The package 1 has the upper housing 11A that is opened upward and the lower housing 11B that is opened downward. The upper housing 11A and the lower housing 11B are disposed back to back such that both closed parts (bottom parts) are opposite to each other with respect to a substrate 11C.

The upper housing 11A is a housing as a rectangular parallelepiped recess that is opened upward. On the bottom part of the upper housing 11A, mounting electrodes 16 and 17 respectively made of metal films are formed. The mounting electrodes 16 and 17 are arranged side by side in the short-side direction of the package 1. Also, on the outer peripheral part of the upper housing 11A, a rectangular-shaped sealing part 10 is formed so as to be located at a position higher than the bottom part. On the sealing part 10, metal layers are formed.

The mounting electrodes 16 and 17 are each made of a plurality of metal layers constituted of a W (tungsten) layer, a Ni (nickel) layer, and a Au (gold) layer laminated in this order. The W layer is integrally formed with the ceramic material forming the package 1 by firing. The Ni layer and the Au layer are formed on the W layer by plating. The sealing part 10 has the same metal layer structure as that of the mounting electrodes 16 and 17, i.e. the laminated structure of the W layer, the Ni layer and the Au layer. Furthermore, mounting electrodes 18 and 19 as well as external mounting electrodes 12, 13, 14 and 15 (described later) are manufactured by the same process, and each have the layer structure constituted of the W layer, the Ni layer, and the Au layer laminated in this order.

The lower housing 11B is a housing as a rectangular parallelepiped recess that is opened downward. On the bottom part of the lower housing 11B, the mounting electrodes 18 and 19 respectively made of metal films are formed. The mounting electrodes 18 and 19 are each formed in a rectangular shape having long sides and short sides, and arranged such that the long sides of the respective mounting electrodes face each other in the direction along the long side of the package 1. Alternatively, both mounting electrodes may be arranged side by side in the short-side direction of the package 1.

Also, on four corners of the lower housing 11B, the external mounting electrodes 12, 13, 14 and 15 are respectively provided so as to be located at positions vertically lower than the bottom part. The above external mounting electrodes each have a rectangular shape. Among them, the external mounting electrodes 12 and 14 are electrically connected to the respective mounting electrodes 16 and 17, while the external mounting electrodes 13 and 15 are electrically connected to the respective mounting electrodes 18 and 19, each via inner wirings of the package 1.

### <Configuration of Crystal Resonator Plate>

The crystal resonator plate 2 made of an AT-cut crystal resonator plate has a substantially rectangular plate shape. On respective center parts of the front and rear surfaces of the crystal resonator plate 2, excitation electrodes 21 and 22 are formed. The excitation electrodes 21 and 22 are drawn out to the outer peripheral part of the crystal resonator plate 2 respectively via lead-out electrodes 21a and 22a each formed in a strip shape having a certain width. The excitation electrodes 21 and 22 each have a rectangular shape. On a first main surface of the crystal resonator plate 2, the excitation electrode 21 is drawn out from one short side corner to a short side of the first main surface of the crystal resonator plate 2 via the lead-out electrode 21a. On a second main surface of the crystal resonator plate 2, the excitation electrode 22 is drawn out from one short side corner to a short side of the second main surface of the crystal resonator plate 2 via the lead-out electrode 22a. In this way, the lead-out electrodes 21a and 22a are drawn out to one short side of the crystal resonator plate 2.

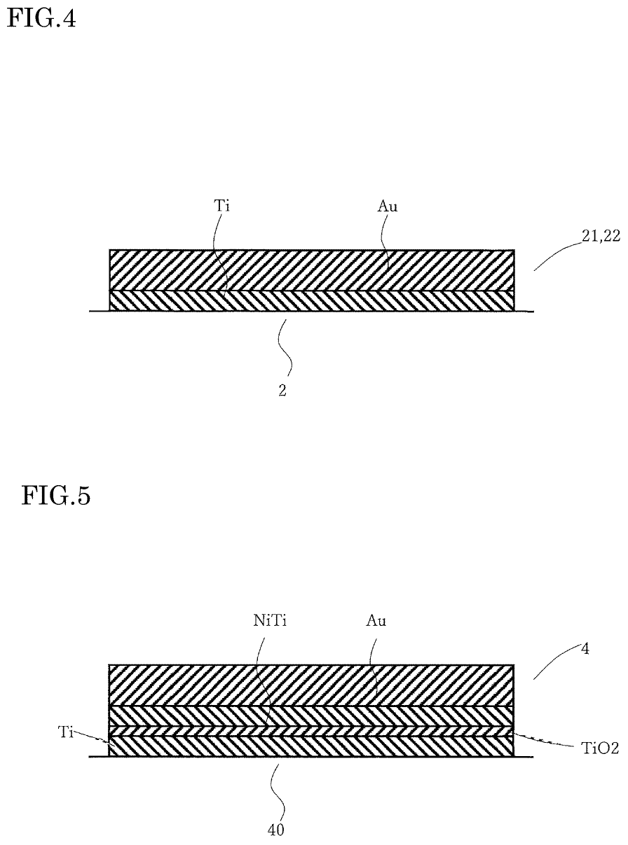

The excitation electrodes 21 and 22 as well as the lead-out electrodes 21a and 22a each have a structure in which thin metal films are laminated. Specifically, as shown in FIG. 4, the above excitation electrodes and the lead-out electrodes each have a laminated structure in which a Ti (titanium) layer is formed to make contact with the crystal resonator plate 2, and a Au (gold) layer is formed thereon. The Ti layer serves as a base layer while the Au layer serves as a main layer. However, the metal film structure may be different from the above example. For example, a Cr (chromium) layer may be used as the metal base, and a Ag (silver) layer may be used as the upper layer. That is, well-known metal structures may be used.

By forming the Ti layer or the Cr layer as the base layer that makes contact with the crystal resonator plate 2, it is possible to form a stable base of the excitation electrodes 21 and 22 in which the metal film has excellent adhesion to the crystal resonator plate 2. Also, by forming the Au layer as the main layer on the surface of the layers, it is possible to ensure the long-term quality stability of the excitation electrodes. Furthermore, since the thermal conductivity is also excellent, it is possible to transmit changes of the environmental temperature to the crystal resonator plate 2 with reduced time lag.

Also, an extremely-thin Cr layer may be formed on the Au layer as the main layer. Alternatively, the base metal layer as the lower layer may be exposed to the upper layer by heat diffusion. With the above-described configurations, the bonding to a conductive resin adhesive (described later) can be improved (i.e. formation of the functional layer).

The excitation electrodes 21 and 22 and the lead-out electrodes 21a and 22a are obtained by integrally laminating and forming the metal film layers by a well-known PVD film formation method such as a vacuum deposition method and a sputtering method.

In this embodiment, the AT-cut crystal resonator plate is used as the crystal resonator plate 2. However, an SC-cut crystal resonator plate or an X-Y-cut tuning fork crystal resonator plate may also be used.

### <Configuration of Thermistor>

The thermistor 4 serves as a temperature sensor, and is a substantially thin single plate-like NTC thermistor. The thermistor 4 includes a rectangular plate-like thermistor element 40 as a base material, and has a thickness of G2. On a first main surface of the plate-like thermistor element 40, the rectangular-shaped working electrodes 41 and 42 are formed so as to have a constant gap G1 therebetween in the long side direction. The working electrodes 41 and 42 each have a rectangular shape constituted of long sides and short sides. The long side has a size corresponding to the size of the short side of the plate-like thermistor element 40. On a second surface of the plate-like thermistor element 40, a rectangular-shaped relay electrode 43 is formed so as to cover the entire surface.

The thermistor 4 serves as an electronic component having a terminal as a resistor, with the working electrode 41 on one side and the working electrode 42 on the other side, both formed on the plate-like thermistor element 40. The conductive path leads from the working electrode 41 to the working electrode 42 via the relay electrode 43. With this configuration, it is possible to considerably increase the cross sectional area of the conductive path, and also to provide the conductive path in which the surfaces of the working electrodes face the surface of the relay electrode. Thus, it is possible to reduce the resistance value with a small area, which leads to characteristics easily stabilized and an improved withstand voltage.

When the working electrodes 41 and 42 are adjacent to each other, a direct path from the working electrode 41 to the working electrode 42 is sometimes dominant as the conductive path depending on the voltage applied, with the result that the desired resistance value cannot be obtained. Therefore, in this embodiment, a distance G2a, a distance G2b and the distance G1 are set to satisfy the following inequality: G2a+G2b<G1, where G2a represents the distance between the working electrode 41 and the relay electrode 43, G2b represents the distance between the working electrode 42 and the relay electrode 43, and G1 represents the distance between the working electrodes 41 and 42. With this setting, it is possible to obtain the desired resistance value, which leads to stabilization of accuracy of the thermistor as the temperature sensor.

The larger the contact area of the thermistor 4 with the package 1 becomes, and furthermore the closer the thermistor 4 is located to the crystal resonator plate 2, the more exactly the temperature of the crystal resonator plate 2 can be detected. Therefore, from the viewpoint of temperature measurement, the area occupied by the working electrodes 41 and 42 formed on the thermistor 4 are preferably large with respect to the area of the plate-like thermistor element 40. With this configuration, it is possible to increase the contact area. However, if this area is too large, a short circuit between the adjacent working electrodes 41 and 42 or a short circuit caused by the conductive bonding material is likely to occur. On the other hand, when the contact area becomes small, the accuracy in detection of the temperature of the crystal resonator plate 2 is degraded.

Thus, when the total area of the working electrodes 41 and 42 occupies 40 to 85% of the area of the first main surface of the plate-like thermistor element 40, it is possible to stably detect the temperature, although it also depends on the desired resistance value. When the total area occupies not more than 40%, the working electrodes 41 and 42 of the thermistor 4 are too small and thus it is not possible to correctly detect temperature information on the crystal resonator plate 2. Furthermore, the resistance value of the thermistor 4 becomes too high, and thus it may degrade the temperature detection performance as the temperature sensor. When the total area occupies not less than 85%, the risk of short circuit including the case caused by the above-described conductive bonding material increases, and once the short circuit occurs, the thermistor 4 does not function as the temperature sensor any more.

Here, a specific example of the respective sizes of the thermistor 4 is shown below. As the external size of the thermistor 4, the long side is 0.8 mm, the short side is 0.6 mm, the thickness is 0.05 mm, and the area is 0.48 mm². As the external size of each of the working electrodes 41 and 42 formed on the plate-like thermistor element 40, the long side (i.e. in the short side direction of the plate-like thermistor element 40) is 0.52 mm, the short side (i.e. in the long side direction of the plate-like thermistor element 40) is 0.3 mm, and the area is 0.156 mm². With this configuration, the total area of the working electrodes 41 and 42 is set to about 65% of the area of the temperature sensor. Also, the distance G2a between the working electrode 41 and the relay electrode 43 and the distance G2b between the working electrode 42 and the relay electrode 43 are each set to 0.05 mm. The distance G1 between the respective working electrodes 41 and 42 is set to 0.12 mm. Thus, the above-described inequality G2a+G2b<G1 is satisfied.

Another specific example is shown below. As the external size of the thermistor 4, the long side is 0.7 mm, the short side is 0.6 mm, the thickness is 0.04 mm, and the area is 0.42 mm². As the external size of each of the working electrodes 41 and 42 formed on the plate-like thermistor element 40, the long side (i.e. in the short side direction of the plate-like thermistor element 40) is 0.58 mm, the short side (i.e. in the long side direction of the plate-like thermistor element 40) is 0.3 mm, and the area is 0.174 mm². With this configuration, the total area of the working electrodes 41 and 42 is set to about 83% of the area of the temperature sensor. Also, the distance G2a between the working electrode 41 and the relay electrode 43 and the distance G2b between the working electrode 42 and the relay electrode 43 are each set to 0.04 mm. The distance G1 between the respective working electrodes 41 and 42 is set to 0.09 mm. Thus, the above-described inequality G2a+G2b<G1 is satisfied.

Furthermore, another specific example is shown below. As the external size of the thermistor 4, the long side is 1.2 mm, the short side is 0.6 mm, the thickness is 0.05 mm, and the area is 0.72 mm². As the external size of each of the working electrodes 41 and 42 formed on the plate-like thermistor element 40, the long side (i.e. in the short side direction of the plate-like thermistor element 40) is 0.6 mm, the short side (i.e. in the long side direction of the plate-like thermistor element 40) is 0.4 mm, and the area is 0.24 mm². With this configuration, the total area of the working electrodes 41 and 42 is set to about 66% of the area of the temperature sensor. Also, the distance G2a between the working electrode 41 and the relay electrode 43 and the distance G2b between the working electrode 42 and the relay electrode 43 are each set to 0.05 mm. The distance G1 between the respective working electrodes 41 and 42 is set to 0.4 mm. Thus, the above-described inequality G2a+G2b<G1 is satisfied. The above sizes may be appropriately designed according to the sizes and characteristics of the crystal resonator device, or to the required specifications of the crystal resonator device Xtl with a thermistor.

As the single plate-like thermistor 4, for example, a Mn—Fe—Ni—Ti material is made into slurry with a binder. Then, a green sheet of the thermistor wafer is prepared using a thick film formation technology such as a screen printing technology or a doctor blade technology. This is subjected to firing technology so as to sinter and form the plate-like thermistor wafer.

On the single plate-like thermistor wafer, an electrode film (metal film) is formed by sputtering, and then patterning is performed by a photolithography technology. As specific metal film layers (metal materials), a laminated film structure may be adopted, as shown in FIG. 5, which is constituted of: a Ti (titanium) layer as a base layer formed to make contact with the plate-like thermistor element 40; a TiO₂ (titanium oxide) layer as a barrier layer formed on the Ti layer; a NiTi layer made of an alloy of a Ni (nickel) layer and a Ti layer formed on the TiO₂ layer; and a Au (gold) layer as a main layer formed on the surface.

In the case where the above laminated film structure constituted of the Ti layer, the TiO₂ layer, the NiTi layer and the Au layer is adopted, it is possible to perform stable conductive bonding with low occurrence of solder leaching when the thermistor 4 is finally bonded to the mounting board by solder. Also in the above-described laminated structure, the TiO₂ layer is not necessarily required to be formed. More specifically, the electrodes of the thermistor 4 (i.e. the working electrodes 41 and 42, and the relay electrode 43) may each have a laminated film structure constituted of: the Ti (titanium) layer as the base layer formed to make contact with the plate-like thermistor element 40; the NiTi layer made of an alloy of a Ni (nickel) layer and a Ti layer formed as an intermediate layer on the Ti layer; and the Au (gold) layer as the main layer (uppermost layer) formed on the surface.

Also, the metal film structure of the working electrodes 41 and 42 may be different from the metal film structure of the relay electrode 43. For example, the metal film structure of the working electrodes 41 and 42 may be the laminated structure constituted of the Ti film, the NiTi film and the Au film as described above, while the metal film structure of the relay electrode 43 may be a laminated structure constituted of the Ti film and the Au film. As an example of the film thickness of each metal film, in the case of the working electrodes 41 and 42, the Ti film has the thickness of 250 nm, the NiTi film has the thickness of 150 nm, and the Au film has the thickness of 150 nm. Also in the case of the relay electrode 43, the Ti film has the thickness of 5 nm, and the Au film has the thickness of 150 nm. Alternatively, in the working electrodes 41 and 42 also, the thickness of the Ti film may be 5 nm and the thickness of the Au film may be 150 nm, that is, the Ti film and the Au film of the working electrodes 41 and 42 each have the same thickness as those of the relay electrode 43. In this case, it is possible to simultaneously form the working electrodes 41 and 42 and the relay electrode 43 in the same film-forming environment.

Alternatively, another laminated film structure may be adopted, which is constituted of: a Cr (chromium) layer formed to make contact with the plate-like thermistor element 40; a NiCr layer made of an alloy of a Ni layer and a Cr layer formed on the Cr layer; and a Au (gold) layer formed as an uppermost layer.

By forming the Ti layer or the Cr layer as the base layer that makes contact with the plate-like thermistor element 40, it is possible to form a stable base of the excitation electrodes 21 and 22 in which the metal film has excellent adhesion to the crystal resonator plate 2. Also, by forming the Au layer as the main layer, it is possible to ensure the long-term quality stability of the excitation electrode films. Furthermore, since the thermal conductivity is also excellent, it is possible to transmit changes of the environmental temperature to the plate-like thermistor element 40 with reduced time lag. The Au is a chemically stable metal material that also has an excellent thermal conductivity, which means that a chemical change of the surface such as oxidation is not likely to occur and accordingly electrical characteristics can be stabilized. By using the Au as the metal material of the main layer, the thermal conductive property can be stabilized, and thus it is possible to reduce difference in time for transmission of heat from the outside to the crystal resonator plate 2 and to the thermistor 4. The Ti and the Cr have excellent adhesion to the crystal plate and the ceramic as the thermistor material when forming the film, which leads to enhancement of the mechanical strength of the excitation electrodes 21 and 22 and the working electrodes 41 and 42. Furthermore, use of the same metal material as the base metal of the above respective electrodes contributes to reduction of difference in the thermal conduction, which results in reduction of difference in time for transmission of heat from the outside to the crystal resonator plate 2 and to the thermistor 4. In addition to the above, by using the Au as the metal material of the main layer of the mounting electrodes 16, 17, 18 and 19, the thermal conductive property can be stabilized, and thus it is possible to further reduce difference in time for transmission of heat from the outside to the crystal resonator plate 2 and to the thermistor 4.

Also, by making the respective metal materials of the above main layers have the same thickness, it is possible to reduce difference in the thermal conduction, which results in reduction of difference in time for transmission of heat to the crystal resonator plate 2 and to the thermistor 4.

Furthermore, the Au may be used as the upper layer to form a very thin Cr layer thereon, or the base metal layer as the lower layer may be exposed to the upper layer by heat diffusion, so that the adhesion to the conductive resin adhesive (described later) is improved.

In this way, by forming the thin metal film on the single plate-like thermistor element 40 by the PVD film formation method such as the sputtering method and the vacuum deposition method, an extremely thin plate-like thermistor can be obtained. In the plate-like thermistor, the surface roughness can be decreased by lapping its surface in the state of the thermistor wafer. In this configuration, it is possible to stably form the electrode film (metal film) and also to improve manufacturing accuracy. Thus, the performance of the temperature sensor can be highly improved.

By making the plate-like thermistor element 40 as a single plate, heat that is input from the working electrodes 41 and 42 can cause the plate-like thermistor element 40 to have the temperature of the input heat for a short time. That is, the single plate-like thermistor 4 can detect changes in the outside temperature with reduced time lag. Especially by setting the thickness of the plate-like thermistor element 40 to 0.05 mm or less, the heat transmitted to the working electrodes 41 and 42 (i.e. the temperature fluctuation information) is quickly transmitted to the plate-like thermistor element 40. Thus, it is possible to extremely quickly follow the changes in the outside temperature.

Also, by using the Au to the working electrodes 41 and 42 and the relay electrode 43 formed on the plate-like thermistor element 40, it is possible to obtain an excellent thermal conduction, which leads, together with the single plate structure of the plate-like thermistor element 40 as described above, to detection of the changes in the outside temperature with reduced time lag.

Also in this embodiment, the metal film used to the relay electrode 43 on the second surface of the plate-like thermistor element 40 functions also as a heat transfer part, the thermal response speed of the entire thermistor 4 can be improved, which results in detection of the changes in the outside temperature with reduced time lag.

Especially, by using the Au layer as the main layer of the working electrodes 41 and 42 and the relay electrode 43, it is possible to improve heat transfer performance, which leads to detection of the changes in the outside temperature with further reduced time lag.

### <Hermetical Sealing by Lid>

The lid 3 is made of a thin metal plate or a thin ceramic plate, and formed in the rectangular shape corresponding to the external size of the sealing part 10 of the package 1. The configuration of the lid 3 and the sealing part 10 differs depending on the hermetically sealing manner of the package 1. For example, when the lid 3 is bonded to the sealing part 10 by seam welding, Kohbar is used as the core material of the lid 3, and a Ni plating film is formed thereon. Also, a ring-shaped metal frame is brazed and soldered onto the sealing part 10. Then, the lid 3 and the metal frame are bonded to each other by seam welding in, for example, a vacuum atmosphere or an inert gas atmosphere. Thus, the inside of the package 1 (i.e. the inside of the upper housing 11A) can be a steady state in the vacuum atmosphere or the inert gas atmosphere.

When the hermetical sealing is performed by brazing and soldering using a metal brazing material such as a AuSn brazing material, for example, the AuSn brazing material is peripherally preformed on the lid 3, while a Au plating is formed on the upper layer of the sealing part 10. Then, the lid 3 and the sealing part 10 are heated in a predetermined atmosphere and a temperature environment so that they are hermetically sealed by metal brazing and soldering.

<Assembly of Crystal Resonator Device with Thermistor>

Here, an example of assembly of the crystal resonator device Xtl with a thermistor is described. A paste conductive resin adhesive S1 is applied onto the mounting electrodes 16 and 17 in the upper housing 11A of the package 1 using a dispenser or the like. An example of the conductive resin adhesive S1 is made of a silicone resin adhesive containing a metal filler. However, other resin materials such as a polyimide resin material may be used.

On the thus applied conductive resin adhesive S1, the crystal resonator plate 2 on which the electrodes are formed is mounted. More specifically, the crystal resonator plate 2 is installed in the upper housing 11A in a state in which respective parts of the lead-out electrodes 21a and 22a are bonded to the respective pieces of conductive resin adhesive S1. Then, the conductive resin adhesive S1 is heated and cured so as to conductively bond (electrically and mechanically bond) the crystal resonator plate 2 to the mounting electrodes 16 and 17. As necessary, the conductive resin adhesive S1 may be applied again from above the crystal resonator plate 2. In this embodiment, an example is shown, in which the conductive resin adhesive S1 is applied again.

Then, the upper housing 11A is hermetically sealed by the lid 3, which is performed by bonding the lid 3 to the sealing part 10. In this embodiment, they are sealed by a metal brazing material using a metal brazing material S2 (i.e. AuSn brazing material).

After that, the thermistor 4 is conductively bonded to the lower housing 11B. The conductive resin adhesive S1 is applied onto the mounting electrodes 18 and 19 using a dispenser or the like. The thermistor 4 is installed in the lower housing 11B in a state in which the working electrodes 41 and 42 are respectively located so as to correspond to the respective pieces of conductive resin adhesive S1. Then, the conductive resin adhesive S1 is heated and cured so as to conductively bond (electrically and mechanically bond) the thermistor 4 to the mounting electrodes 18 and 19. As the conductive bonding of the thermistor 4, solder bonding may also be used.

Then, a resin material M is injected into the lower housing 11B by the dispenser or the like so as to cover the thermistor 4 by the resin material M. After that, the resin material M is heated and cured. In this embodiment, the polyimide resin is used as the resin material M. However, other resin materials may be used. In this way, since the thermistor 4 is protected from the outside air, it is possible to stably detect the temperature.

When the solder bonding is performed as the conductive bonding of the thermistor 4, it is preferable that, as to the film thickness, the Ti film has the thickness of 250 nm, the NiTi film has the thickness of 150 nm, and the Au film has the thickness of 150 nm, as described above. After the solder bonding, the Au layer on each surface of the working electrodes 41 and 42 has been subjected to solder leaching and thus sometimes disappeared from the electrode film structure, however, it is still possible to ensure necessary electrical bonding by the bonding part, the NiTi film and the Ti film as the base layer. Also, a TiO₂ film having the film thickness of, for example, 0.5 to 3 nm may be formed on the upper surface of the Ti film. In this case, it is possible to protect the Ti layer as the base layer from solder.

The resin material M is not necessarily required to be used. Alternatively, the resin material M is injected only into the bottom part of the lower housing 11B. In such a case where the resin material M is injected only into the bottom part, the mounting electrodes 18 and 19 and the working electrodes 41 and 42 bonded to each other by the conductive resin adhesive S1 are covered and protected by the resin material M while the relay electrode 43 is exposed. Thus, it is possible to ensure the bonding strength of the thermistor 4 while detecting the surrounding temperature with reduced time lag.

After a predetermined characteristic inspection is performed, the production process of the crystal resonator device Xtl with a thermistor is completed.

In this embodiment, both the crystal resonator plate 2 and the thermistor 4 have a single plate structure, and the electrode film made of the metal film layers is formed on the respective surfaces thereof. Furthermore, both the crystal resonator plate 2 and the thermistor 4 have the Au as the main layer of the metal film layers. With this configuration, even when the heat is conducted through the package 1, for example, the temperature increase information or the temperature decrease information is transmitted to the crystal resonator plate 2 and the thermistor 4 with reduced time lag. Thus, the difference between the temperature detected by the thermistor 4 as the temperature sensor and the temperature of the crystal resonator plate 2 is extremely small, which results in accurate and appropriate temperature compensation based on the frequency information of the crystal resonator plate 2 and the temperature information of the thermistor 4.

Also in this embodiment, the package 1 has two housings (the upper housing 11A and the lower housing 11B) that are opened respectively upward and downward with the substrate being interposed therebetween, as the housing structure of the package. The crystal resonator plate 2 is conductively bonded to one housing (the upper housing 11A) while the thermistor 4 is conductively bonded to the other housing (the lower housing 11B). The crystal resonator plate 2 and the thermistor 4 are located respectively on the front surface and the rear surface of the substrate so as to be opposite to each other. With this configuration, it is possible to eliminate difference in the thermal conduction between the crystal resonator plate 2 and the thermistor 4, which leads to improvement of the accuracy in the detection of the temperature.

### Second Embodiment

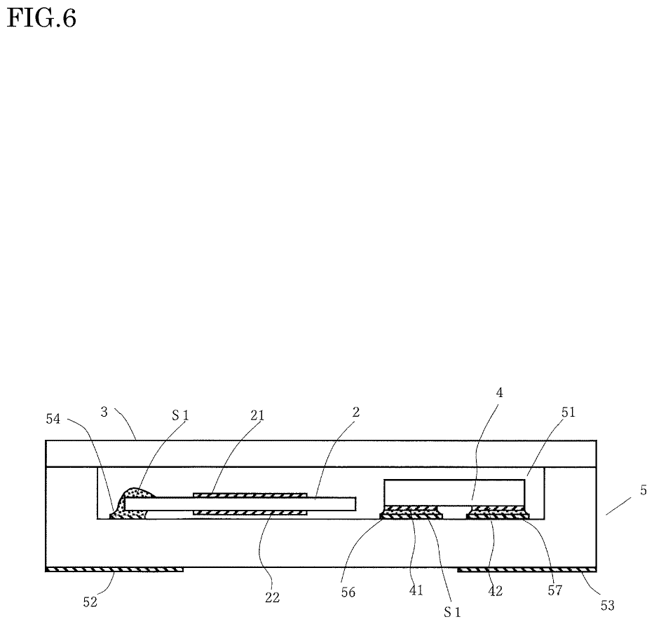

Hereinafter, a second embodiment is described with reference to FIG. 6.

In the second embodiment, the crystal resonator plate 2 and the thermistor 4 are housed in a housing 51 of a package 5. The package 5 is made of ceramic on which inner wirings are formed, and has the housing 51 that is opened upward.

On the bottom part of the housing 51 are formed mounting electrodes 54 and 55 for the crystal resonator plate 2 (55 is not shown in FIG. 6) and mounting electrodes 56 and 57 for the thermistor 4. On the rear surface thereof, external mounting electrodes 52 and 53 are formed.

In the same way as the first embodiment, the crystal resonator plate 2 is made of a rectangular plate-shaped AT-cut crystal resonator plate as the base material. The excitation electrodes 21 and 22 as well as the lead-out electrodes 21a and 22a (not shown) are respectively formed on both main surfaces thereof. The pair of working electrodes 41 and 42 is formed on a first main surface of the thermistor 4 so as to have a constant gap therebetween. However, unlike the first embodiment, no relay electrode is formed. The electrode film formation on the crystal resonator plate 2 and the thermistor 4 is performed by the PVD film formation method such as sputtering. The crystal resonator plate 2 and the thermistor 4 are conductively bonded, via the same conductive resin adhesive S1, to the respective mounting electrodes by thermal curing. After that, the package is hermetically sealed by the lid 3.

In this embodiment, the single plate-like crystal resonator plate 2 and the single plate-like thermistor 4 are arranged side by side in the single housing 51. Also, on both the single plate-like crystal resonator plate 2 and the thermistor 4, the electrodes are formed as the metal film layers including the Au as the main layer by the PVD film formation method. Thus, the respective temperatures of the crystal resonator plate 2 and the thermistor 4 can be changed without time lag according to the change in the environmental temperature. Also, it is possible to reduce the height of the crystal resonator device Xtl with a thermistor. Furthermore, since the conductive bonding is performed using the same conductive resin adhesive S1, the internal atmosphere after hermetical sealing is stable, which reduces characteristic changes. In addition, the thermal curing of the adhesive can be performed at once, which leads to excellent productivity and reduction in costs.

Also, by the configuration in which the crystal resonator plate 2 and the thermistor 4 are both housed in the single housing 51, it is possible to install the crystal resonator plate 2 and the thermistor 4 so as to be adjacent to each other, which leads to reduction of difference in the thermal change therebetween. Furthermore, since the conductive resin adhesive S1 is used inside the single housing 51, gas is not likely to be generated after bonding, which results in stability of the characteristics of the crystal resonator plate 2. Conventionally, the conductive bonding of the laminated thermistor is performed by solder, and thus the atmosphere inside the package 1 is sometimes contaminated by remaining flux or the like. However, using the conductive resin adhesive S1 to the bonding of the crystal resonator plate 2 and to the bonding of the thermistor 4 stabilizes the atmosphere inside the package 1 (the vacuum atmosphere or the inert gas atmosphere), which contributes to stabilization of the characteristics of the crystal resonator plate 2 (i.e. operations of the crystal resonator). Also, since the same conductive resin adhesive S1 is used, it is possible to reduce difference in the thermal conduction, which results in improvement of the accuracy in the temperature detection.

### Third Embodiment

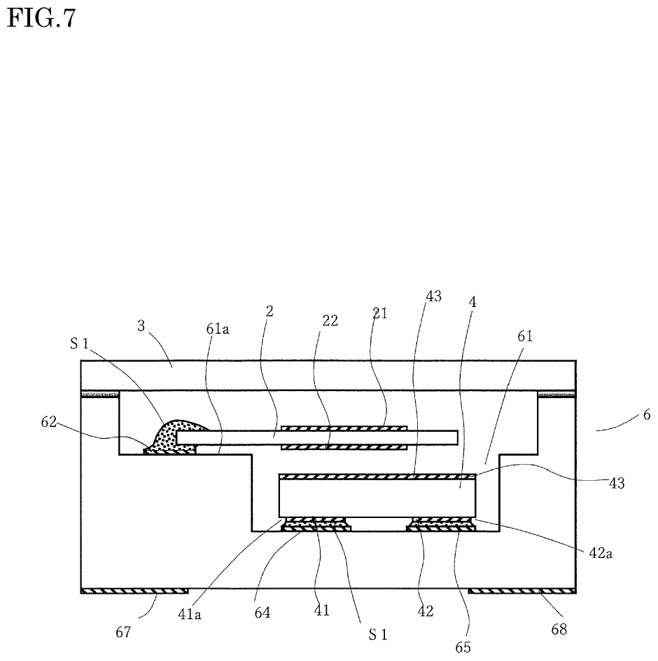

Hereinafter, a third embodiment is described with reference to FIG. 7.

In the third embodiment, the crystal resonator plate 2 and the thermistor 4 are housed so as to be arranged in the height direction in a housing 61 of a package 6. The package 6 is made of ceramic on which inner wirings are formed, and has the housing 61 that is opened upward. The housing 61 is provided with a step part 61a therein, and on the step part 61a, mounting electrodes 62 and 63 (63 is not shown in FIG. 7) are formed. On the bottom part of the housing 61 are formed mounting electrodes 64 and 65 for the thermistor. On the rear surface thereof, external mounting electrodes 67 and 68 are formed.

In the same way as the first embodiment, the crystal resonator plate 2 is made of an AT-cut crystal resonator plate as the base material. The excitation electrodes 21 and 22 as well as the lead-out electrodes 21a and 22a (not shown) are respectively formed on both main surfaces thereof. The pair of working electrodes 41 and 42 is formed on the first main surface of the thermistor 4 so as to have a constant gap therebetween, while the relay electrode 43 is formed on a second main surface thereof so as to cover the entire of the second main surface. In this embodiment, the pair of working electrodes 41 and 42 are each formed in a rectangular shape having long sides and short sides. Also, electrodeless parts 41a and 42a, where no end part of the electrode films reaches, are provided on the end region of the plate-like thermistor element 40. With this configuration, even when the applied amount of the conductive resin adhesive S1 is too large, the conductive resin adhesive S1 is not likely to reach the relay electrode 43 formed above, which leads to prevention of occurrence of short cut between the electrodes due to the conductive resin adhesive S1. The electrodeless part may be formed on the outer periphery of the relay electrode 43.

Furthermore, in this embodiment, the relay electrode 43 is disposed below the excitation electrodes 21 and 22 formed on the crystal resonator plate 2, and furthermore the lid 3 (described later) is made of a metal material. Thus, the crystal resonator plate 2 is interposed between the metal materials in the vertical direction. In this way, it is possible to obtain an electromagnetic shielding effect that external noise does not affect the crystal resonator plate 2.

The electrode film formation on the crystal resonator plate 2 and the thermistor 4 is performed by the PVD film formation method such as sputtering. The crystal resonator plate 2 and the thermistor 4 are conductively bonded, via the same conductive resin adhesive S1, to the respective mounting electrodes by thermal curing. After that, the package is hermetically sealed by the lid 3.

In this embodiment, the single plate-like crystal resonator plate 2 and the single plate-like thermistor 4, on which the electrodes are formed by the PVD film formation method, are arranged in the single housing 61 in the vertical direction. Thus, the respective temperatures of the crystal resonator plate 2 and the thermistor 4 can be changed without time lag according to the change in the environmental temperature. Furthermore, since the conductive bonding is performed using the same conductive resin adhesive S1, the internal atmosphere after hermetical sealing is stable, which reduces characteristic changes. In addition, the thermal curing of the conductive resin adhesive S1 can be performed at once, which leads to excellent productivity and reduction in costs.

### Fourth Embodiment

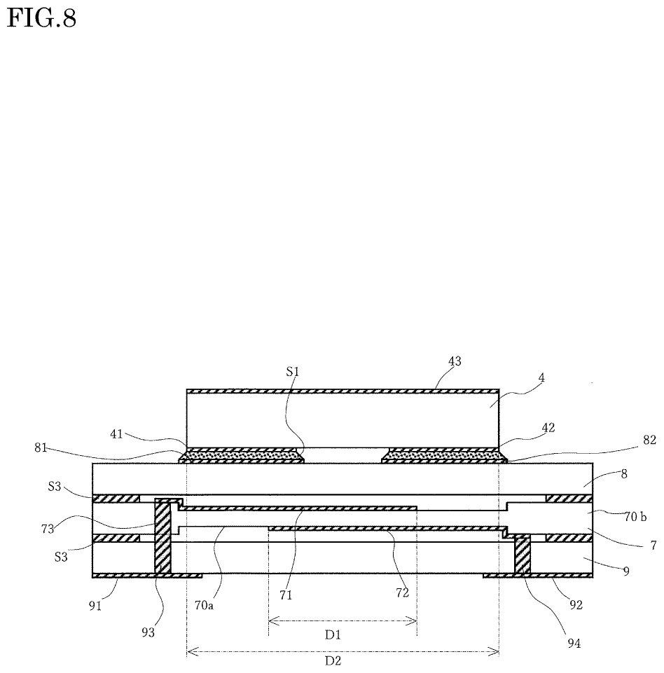

Hereinafter, a fourth embodiment is described with reference to FIG. 8.

In the fourth embodiment, a crystal resonator device Xtl with a thermistor is shown, which includes: a three-layer crystal resonator device; and a rectangular single plate-like thermistor 4. The three-layer crystal resonator device includes: a rectangular plate-shaped crystal resonator plate 7 having surfaces on which excitation electrodes 71 and 72 each made of a plurality of metal film layers are formed; a rectangular-shaped first sealing member 8 that is bonded to a front surface of the crystal resonator plate 7; and a rectangular-shaped second sealing member 9 that is bonded to a rear surface of the crystal resonator plate 7. The rectangular single plate-like thermistor 4 has a surface on which the working electrodes 41 and 42 made of a plurality of metal film layers are formed, and is bonded to the first sealing member 8 of the crystal resonator device.

The center part of the crystal resonator plate 7 is a thin vibrating part 70a. On the front and rear surfaces of the thin vibrating part 70a, rectangular-shaped excitation electrodes 71 and 72 are respectively formed so as to be opposite to each other. Also, an outer peripheral part of the crystal resonator plate 7 is an outer peripheral part 70b that has a thickness larger than the thickness of the vibrating part 70a. Thus, the crystal resonator plate 7 has, as a whole, a mesa structure.

The first sealing member 8 has a first main surface and a second main surface. On the first main surface, mounting electrodes 81 and 82 are formed. On the second main surface, a sealing part S3 made of metal films is provided on an outer peripheral part so as to be bonded to the outer peripheral part 70b of the crystal resonator plate 7.

The second sealing member 9 has a first main surface and a second main surface. On the first main surface, the sealing part S3 made of metal films is provided on an outer peripheral part so as to be bonded to the outer peripheral part 70b of the crystal resonator plate 7. On the second main surface, external mounting electrodes 91 and 92 are formed. The excitation electrode 71 is connected, via the lead-out electrode, to a metal via hole (conductive path) 73 formed in a through hole penetrating the front and rear surfaces of the crystal resonator plate 7. This metal via hole 73 is conductively connected to a metal via hole 93 formed in a through hole penetrating the front and rear surfaces of the second sealing member 9. The excitation electrode 72 is conductively connected, via the lead-out electrode, to a metal via hole 94. Finally, the excitation electrodes 71 and 72 are respectively electrically connected to the external mounting electrodes 91 and 92.

The thermistor 4 has the same configuration as the thermistor shown in FIG. 1. On the first main surface of the rectangular single plate-like thermistor element 40, the pair of working electrodes 41 and 42 is formed. On the second surface of the rectangular single plate-like thermistor element 40, the relay electrode 43 is formed. The thermistor 4 is mounted on the mounting electrodes 81 and 82, and the working electrodes 41 and 42 of the thermistor 4 are conductively bonded thereto respectively via the conductive resin adhesive S1.

The excitation electrodes 71 and 72 and the lead-out electrodes formed on the crystal resonator plate 7 each have a laminated film structure in which the Ti layer is formed so as to make contact with the crystal resonator plate 7, and the Au layer is formed thereon as the main layer. Also, the mounting electrodes 81 and 82 of the first sealing member 8 each have a laminated film structure in which the Ti layer is formed as the base layer so as to make contact with the crystal plate, and the Au layer is formed thereon as the main layer. Furthermore, the external mounting electrodes 91 and 92 of the second sealing member 9 each have a laminated film structure in which the Ti layer is formed as the base layer so as to make contact with the crystal plate, the NiTi alloy layer is formed thereon, and the Au layer is formed thereon as the main layer. Such film formation is performed using the photolithography technology, by the sputtering method or the vacuum deposition method.

In this embodiment, the rectangular-shaped relay electrode 43 is formed so as to cover the entire of the second main surface of the plate-like thermistor element 40, and thus covers, in plan view, the excitation electrodes 71 and 72 formed respectively on the front surface and the rear surface of the crystal resonator plate 7 so as to be opposite to each other. That is, as can be seen from FIG. 8, the size D2 of the relay electrode 43 is larger than the respective sizes D1 of the excitation electrodes 71 and 72, and thus the relay electrode 43 covers, in plan view, the excitation electrodes 71 and 72. In this way, since the relay electrode 43 and the excitation electrodes 71 and 72 are overlapped with each other in plan view, electromagnetic noise from the outside to the excitation electrodes 71 and 72 is suppressed, which contributes to stabilization of the characteristics of the crystal resonator device. Since the plate-like thermistor element 40 itself is a conductor, the above function and effect can be obtained even when the relay electrode 43 is not formed to cover the entire of the surface of the plate-like thermistor element 40.

### Fifth Embodiment

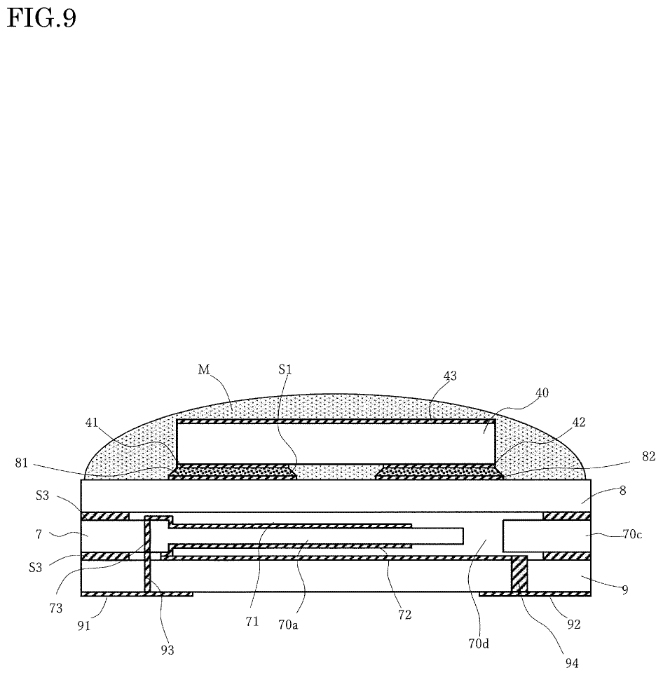

Hereinafter, a fifth embodiment is described with reference to FIG. 9.

In the fifth embodiment, the essential configuration of the crystal resonator device is the same as that disclosed in the fourth embodiment. Thus, the description is partly omitted. The crystal resonator plate 7 includes the vibrating part 70a and a frame body part 70c. A penetrating part 70d is formed along almost all the outer periphery of the vibrating part 70a, and a part of the vibrating part 70a and a part of the frame body part 70c are integrally connected via a connection part (not shown). The excitation electrodes 71 and 72 are drawn out to the frame body part through the connection part, and furthermore drawn out to the external mounting electrodes 91 and 92 via the metal via holes 73, 93, 94 and the like.

The thermistor 4 mounted on the crystal resonator device is molded by the resin material M so as to protect the mounting electrodes 81 and 82, the working electrodes 41 and 42, and the relay electrode 43 from the outside air.

In this embodiment also, the crystal resonator plate 7 and the thermistor 4 are each a single plate, and the Au is used as the main layer of the metal film structure of the excitation electrodes 71 and 72 and the working electrodes 41 and 42.

The foregoing embodiments are to be considered in all respects as illustrative and not limiting. The technical scope of the present invention is indicated by the appended claims rather than by the foregoing description, and all modifications and changes that come within the meaning and range of equivalency of the claims are intended to be embraced therein.

This application claims priority based on Patent Application No. 2021-182803 filed in Japan on Nov. 9, 2021. The entire contents thereof are hereby incorporated in this application by reference.

### DESCRIPTION OF THE REFERENCE NUMERALS

1, 5, 6 Package
11A Upper housing
11B Lower housing
12, 13, 14, 15, 52, 53, 67, 68, 91, 92 External mounting electrode
16, 17, 18, 19, 54, 55, 56, 57, 62, 63, 64, 65, 81, 82 Mounting electrode
2, 7 Crystal resonator plate
21, 22 Excitation electrode
3 Lid
4 Thermistor
41, 42 Working electrode
43 Relay electrode
8 First sealing member
9 Second sealing member
73, 93, 94 Metal via hole
S1 Conductive resin adhesive
S2 Metal brazing material
M Resin material

1. A crystal resonator device with a thermistor, comprising:
a crystal resonator plate on respective surfaces of which a pair of excitation electrodes each constituted of a plurality of metal film layers is formed;
a single plate-like thermistor on a surface of which a pair of working electrodes each constituted of a plurality of metal film layers is formed; and
a single package in which the crystal resonator plate and the single plate-like thermistor are housed, wherein
a main layer of each of the pair of excitation electrodes and a main layer of each of the pair of working electrodes are made of a same metal material.

2. A crystal resonator device with a thermistor, comprising:
a crystal resonator device including: a crystal resonator plate on respective surfaces of which a pair of excitation electrodes each constituted of a plurality of metal film layers is formed; a first sealing member bonded to a first main surface of the crystal resonator plate; and a second sealing member bonded to a second main surface of the crystal resonator plate; and
a single plate-like thermistor on a surface of which a pair of working electrodes each constituted of a plurality of metal film layers is formed, the single plate-like thermistor bonded to the first sealing member of the crystal resonator device, wherein
a main layer of each of the pair of excitation electrodes and a main layer of each of the pair of working electrodes are made of a same metal material.

3. The crystal resonator device with a thermistor according to claim 1, wherein the metal material of the main layer is Au.

4. The crystal resonator device with a thermistor according to claim 1, wherein
a metal film, which makes contact with the crystal resonator plate, of each of the pair of excitation electrodes is made of Ti or Cr, and
a base layer, which makes contact with the single plate-like thermistor, of each of the pair of working electrodes is made of Ti or Cr.

5. The crystal resonator device with a thermistor according to claim 1, wherein
a pair of mounting electrodes each constituted of a plurality of metal film layers is formed on the package, and
a main layer of each of the pair of mounting electrodes is made of a Au layer.

6. The crystal resonator device with a thermistor according to claim 2, wherein
a pair of mounting electrodes each constituted of a plurality of metal film layers is formed on the first sealing member, and
a main layer of each of the pair of mounting electrodes is made of a Au layer.

7. The crystal resonator device with a thermistor according to claim 5, wherein
the pair of mounting electrodes is electrically and mechanically bonded to the pair of excitation electrodes, respectively, each via a conductive resin adhesive, and
the pair of mounting electrodes is electrically and mechanically bonded to the pair of working electrodes, respectively, each via a conductive resin adhesive.

8. The crystal resonator device with a thermistor according to claim 2, wherein the metal material of the main layer is Au.

9. The crystal resonator device with a thermistor according to claim 2, wherein
a metal film, which makes contact with the crystal resonator plate, of each of the pair of excitation electrodes is made of Ti or Cr, and
a base layer, which makes contact with the single plate-like thermistor, of each of the pair of working electrodes is made of Ti or Cr.

10. The crystal resonator device with a thermistor according to claim 6, wherein
the pair of mounting electrodes is electrically and mechanically bonded to the pair of excitation electrodes, respectively, each via a conductive resin adhesive, and
the pair of mounting electrodes is electrically and mechanically bonded to the pair of working electrodes, respectively, each via a conductive resin adhesive.
